(19) United States
(12) Patent Application Publication
(10) Pub. No.: US 2006/0240189 A1
(43) Pub. Date: Oct. 26, 2006

(54) Method for producing carbon nanotubes at low temperature

(75) Inventors: Ming-Der Ger, Taoyuan (TW); Yuh Sung, Taoyuan (TW); Yih-Ming Liu, Taoyuan (TW); Mei-Jiun Shie, Taoyuan (TW); Han-Tao Wang, Taoyuan (TW)

Correspondence Address: BACON & THOMAS, PLLC, 625 SLATERS LANE, FOURTH FLOOR, ALEXANDRIA, VA, 22314, US

(73) Assignee: CHUNG CHENG INSTITUTE OF TECHNOLOGY, NATIONAL DEFENSE UNIVERSITY, Taoyuan (TW)

(21) Appl. No.: 11/246,063

(22) Filed: Oct. 11, 2005

(30) Foreign Application Priority Data
Apr. 20, 2005 (TW) 94112575

(51) Int. Cl. B05D 1/18; C23C 16/00

(52) U.S. Cl. 427/249.1; 427/430.1; 427/437

(57) ABSTRACT

The present invention relates to a low-temperature method for forming carbon nanotubes, which mainly includes preparing a co-catalyst of composite metal particles on a substrate, and growing carbon nanotubes on the substrate by a thermal CVD process at 400° C. The present invention uses a non-isothermal deposition (NITD) and a metal chemical substitution reaction to prepare the co-catalyst particles on the substrate.

### FIELD OF THE INVENTION

The present invention relates to a low-temperature method for producing carbon nanotubes, particularly a method for producing carbon nanotubes by a thermal chemical vapor deposition (CVD) using a co-catalyst.

### BACKGROUND OF THE INVENTION

Since the discovery of carbon nanotubes by Iijima in 1991, there are a few dozens of methods available for synthesizing carbon nanotubes, e.g. Arc method, Laser ablation, and Chemical Vapor Deposition (CVD), etc., wherein the CVD process is commonly viewed as a most convenient process in growing carbon nanotubes. A CVD process not only can uniformly grow carbon nanotubes on a large substrate, but is also convenient in purification.

In a method for producing carbon nanotubes by CVD, a metal catalytic layer is prepared first. Next, said metal catalyst is used to catalyze a carbon source (methanol, toluene, carbon monoxide, acetylene, and methane, etc.) undergoing decomposition to form active carbon atoms which dissolve in said catalyst. When the dissolution is saturated, carbon can precipitate out on the catalyst and gradually grow into carbon tubes.

Conventionally, carbon nanotubes can be made by using a spin-coating process to uniformly distribute cobalt particles 8 nm in size on a silicon substrate as a catalytic metal, and then using a CVD process to produce carbon nanotubes. Since only cobalt metal is used as a catalytic metal, the formation temperature of carbon nanotubes needs to be higher than 700° C. Alternatively, a lithography technique is used to define a photoresist pattern in order to distinguish the region in need of deposition of metal from the region free of deposition on a silicon substrate, depositing nickel metal on the photomask-free region on the silicon substrate by a chemical reduction process, and producing patterned carbon nanotubes by using a microwave plasma CVD process. However, this method not only is tedious and time-consuming, but also has the disadvantage of a conventional method of needing a high temperature during the formation of carbon nanotubes due to the use of single catalytic metal. Furthermore, another method includes using a dry physical process to obtain a catalytic metal membrane, reducing and activating the catalytic metal membrane by hydrogen at a high temperature in order to decompose a mixed carbon source into active carbon atoms, thereby producing carbon nanotubes, carbon particles, and other carbon products with a different structure. However, this method still uses a single-metal catalyst and requires a high reaction temperature.

In the prior art, most of the processes for forming a metal membrane by metallizing a substrate use expensive devices. However, the metal membranes on the substrate all require a high temperature thermal treatment to decompose and shrink the membrane on the substrate in order to form nano metal particles for the convenience of subsequent growth of carbon nanotubes. In order to achieve mass production of uniform carbon nanotubes, this type of method requires a rigorous control on the reaction conditions, and the treatment steps are tedious. Some researchers suggest the use of an ordinary chemical process in preparing nano metal particles. However, the tiny particles are liable to agglomerate. As a result, such a process needs to add a protectant (e.g. SDS, CTAB, PVA) to enable the metal particles in forming a stable colloid. However, such an additive has adverse effects on the subsequent growth of carbon tubes. Furthermore, some researchers use other supports (e.g. porous material, PS particles) for the metal particles to distribute thereon. When utilizing the metal on a support, a high temperature sintering or chemical corrosion process is required to remove the support. This type of method is very tedious and complex.

According to known chemical principles, a noble metal, e.g. Pt, Co, Au, and Ag, etc., is applicable as a catalyst in hydrocracking of gaseous hydrocarbons to form carbon elements at a reduced hydrocracking temperature. It is possible to reduce the formation temperature of carbon nanotubes if the metal catalyst for formation of carbon nanotubes contains another noble metal to reduce the hydrocracking temperature of the carbon source reactant.

Some of the inventors of the present application and their co-worker disclose a method and an apparatus for metallizing a surface of a substrate in U.S. Pat. No. 6,773,760 B, wherein a metallic layer is formed on a substrate by an nonisothermal deposition by electroless plating in a nonhomogenous heating electroless plating solution. The substrate is immersed in the electroless plating solution being heated by a heating device mounted on a bottom of an electroless plating reactor while the heated solution being cooled by a cooling device provided in the reactor, and the surface of the substrate and the bottom forms a gap of 0.1 to 1000 μm. Disclosure of this US patent is incorporated herein by reference.

In the present invention these inventors try to apply a non-isothermal deposition (NITD) method studied by the inventors in the past on a substrate to directly deposit uniform metal catalytic particles, and then use a metal replacement reaction to deposit a noble metal on the catalytic particles, thereby forming a co-catalyst system. Through such a practice, the inventors intend to reduce the formation temperature of carbon nanotubes, while improving the problem of non-uniform dispersion of metal particles in the conventional methods. Meanwhile, such a new practice has the following advantages: no restriction on the type of substrate used, greatly reducing manufacturing cost, and overcoming the problems, such as tedious, and time-consuming, etc., associated with the conventional process.

### SUMMARY OF THE INVENTION

The present invention provides a low-temperature method for producing carbon nanotubes, which comprises:

providing a first metal chemical deposition solution, a substrate, and a reactor equipped with a heater and a cooler; performing an electroless plating reaction to form at least a first metal particle on a surface of said substrate; using a metal substitution method to substitute a portion of the first metal particles on the surface of the substrate with a second metal to form at least a composite metal particle; and forming carbon nanotubes on the surface of said substrate, wherein the reactor contains said first metal chemical deposition solution, and the substrate is immersed in the chemical deposition solution such that a gap is formed between the surface of the substrate and the heater.

The above-mentioned heater according to the present invention has a wide range of heating temperature, preferably about 100˜300° C. Furthermore, the above-mentioned cooler according to the present invention has a wide range of cooling temperature, preferably about −30˜60° C. In the method according to the present invention, the objective of heating and cooling the deposition solution simultaneously is to provide a deposition solution with a non-uniform temperature distribution, and then this chemical deposition solution containing a first metal is used to perform an electroless plating reaction (chemical deposition). Moreover, the gap between the surface of the substrate and the heater according to the present invention is not limited, and is preferably about 10˜1,000 μm. Since the first metal deposition solution according to the present invention is a deposition solution with a temperature gradient, the heating temperature of the substrate is lower than the heating temperature of the heater when a gap is maintained between the substrate and the heater.

The composition of the first metal chemical deposition solution is not limited, and preferably includes a metal salt, a reduction agent, a complexing agent, and a pH adjustment agent. In one embodiment, the metal salt can be selected from the group consisting of nickel sulfate, nickel chloride, cobalt sulfate, cobalt chloride, ferric sulfate, and a combination thereof. However, depending on the process conditions, other type of metal salt can be used as a catalytic metal. In another embodiment, the reduction agent can be an arbitrary known reduction agent, and is preferably selected from the group consisting of sodium hypophosphite, hydrazine sulfate, and a combination thereof. Moreover, the complexing agent according to the present invention is not limited, preferably is selected from the group consisting of amino acetic acid, sodium lactate, and a combination thereof; and the pH adjustment agent can be any conventional pH adjustment agent.

Furthermore, said first metal according to the present invention is not limited, preferably Group VIII metal, and more preferably selected from the group consisting of Fe, Co, Ni, and an alloy thereof. Moreover, said first metal according to the present invention can be used as a catalytic metal for carbon nanotubes. Also, said second metal according to the present invention is not limited, preferably a noble metal, and more preferably selected from the group consisting of Au, Pd, Pt, and Ag.

In one embodiment, said substrate according to the present invention can be any conventional substrate. In one preferred embodiment, said substrate is selected from the group consisting of single-crystal silicon wafer and glass with a coating of poly-silicon, amorphous silicon and indium-tin-oxide (ITO). Furthermore, one feature of the present invention that the substrate can be selected from a wide variety of materials is also an advantage of the present invention.

Said reaction used for formation of carbon nanotubes according to the present invention is not limited, preferably is a thermal CVD process and comprises the following steps: providing a gas as a carbon source, an argon gas as a protective gas for protecting said substrate before and after the CVD reaction, and a high temperature furnace device; installing a substrate having composite metal particles in a high temperature furnace, while concurrently introducing an argon gas; heating the high temperature furnace to a reaction temperature and sequentially introducing an ammonia gas, and said carbon-source gas into the high temperature furnace to form carbon nanotubes; and upon completion of the formation of the carbon nanotubes, introducing argon gas and removing the substrate from the furnace. Wherein, the reaction temperature for formation of carbon nanotubes according to the present invention is not limited, and is preferably above 400° C. Furthermore, the lowest formation temperature of carbon nanotubes according to the present invention is lower than the formation temperature by the conventional thermal CVD process. Thus, this is also one advantage of the present invention. Furthermore, a suitable carbon-source gas according to the present invention can be any conventional gas, and is preferably selected from the group consisting of CO, methanol, toluene, acetylene, methane, and a combination thereof.

The inventors of the present invention apply a non-isothermal deposition (NITD) method studied by the inventors in the past on a substrate to enable the occurrence of a spontaneous homogeneous nucleation reaction in a local region of the deposition solution, so that a large quantity of metal particles are directly adsorbed on the substrate to form metal nano particles as catalytic metal for formation of carbon nanotubes. This method is different from an ordinary CVD process for forming carbon nanotubes which uses a noble metal in a pre-treatment to form a metal catalyst. The present method enables a direct deposition reaction of a metal catalyst on a substrate selected from a wide variety of materials. Furthermore, metal particles formed according to the present invention will naturally be aligned on the substrate. This also solves the problem of agglomeration of the nano metal particles on the substrate in a coating process. Moreover, the present invention uses a chemical metal substitution method to form composite metal particles as a co-catalytic (e.g. Ni—Pd, Ni—Au, Ni—Pt, Co—Pd, and Co—Pt, etc.), thereby greatly reducing the reaction temperature of the thermal CVD process for forming carbon nanotubes.

### BRIEF DESCRIPTION OF THE DRAWINGS

FIG. 1 shows a SEM photo of Pd—Ni composite metal catalytic particles prepared on an ITO-coated glass substrate according to a preferred example of the present invention;

FIG. 2 shows a SEM photo of carbon nanotubes prepared on an ITO-coated glass substrate according to a preferred example of the present invention; and

FIG. 3 shows a TEM photo of carbon nanotubes shown in FIG. 2 with a greater magnification.

### DETAILED DESCRIPTION OF THE INVENTION

The present invention mainly increases the temperature of a local region in the deposition solution within a gap to enable a spontaneous homogeneous nucleation reaction on a substrate, i.e. a NITD reaction taking place within a restricted region in the deposition solution, thereby producing a large amount of nano particles on the substrate. Due to the existence of a gap between the substrate and the heating plate, and the existence of a large quantity of un-paired electrons on the surface of nano particles, metal particles will naturally deposit on the substrate, thereby forming a catalytic particles of a first metal for producing carbon nanotubes according to the present invention.

According to a preferred embodiment of the present invention, a NITD method is used to prepare catalytic metal particles. Then, a substrate deposited with the catalytic metal particles on the surface thereof is immersed in a plating solution of a noble metal, substituting a portion of the first metal on the particles with the noble metal by an isothermal chemical substitution reaction, thereby forming a co-catalyst of composite metal particles. Finally, a thermal CVD process is used to form carbon nanotubes. A method according to this preferred embodiment comprises:

Firstly, providing a substrate and a non-isothermal deposition reactor containing a chemical metal deposition solution, wherein said chemical deposition solution comprises: a metal salt (nickel sulfate or cobalt sulfate), a reduction agent (sodium hypophosphite or hydrazine sulfate), a complexing agent (amino acetic acid or sodium lactate), and a pH adjustment agent.

The reactor used in this preferred embodiment is a shell-and-tube reactor (not limited to this type of reactor), and the space between the shell and the tube of the reactor acts as a cooler through which water from a constant-temperature water reservoir flows for cooling the deposition solution. In this preferred embodiment, the temperature setting of the cooler is 20° C. Furthermore, an aluminum material is used to fasten a heating rod into a heater, and a Pyrex glass is used to insulate the heater at the bottom of the reactor. Said reactor further includes a temperature sensor (a thermocouple sensor in this preferred embodiment), which is fastened at the center of the heater for measuring the heating temperature of the heater. In this example, the heater is set to a heating temperature of 200° C. Moreover, the reactor can be installed with an adjustable substrate carrier for fastening the substrate, and the interior of the carrier is installed with a set of adjustable legs for controlling the gap between the surface of the substrate and the heater to form a tiny reaction region. The non-isothermal reactor mentioned in this preferred embodiment is only one example of the present invention, and the reactor applicable in this invention is not limited. An applicable reactor in this invention is capable of providing a non-uniform temperature in the chemical deposition solution (enabling the deposition solution to develop a temperature gradient) and maintaining a gap between the substrate and the heater (in this example, the gap being 150 μm).

A clean substrate is installed on the substrate carrier, and the adjustable legs are adjusted to a desired height. Next, the chemical metal deposition solution is prepared and loaded into the reactor, and the cooler and the heater are separately set to a desired temperature. Then, the carrier fastened with the substrate is loaded into the reactor. After the temperature of the cooler has become stable, the heater is activated. Metal particles are formed on the surface of the substrate by the non-isothermal electroless deposition reaction in the gap. Next, the substrate deposited with the metal particle catalyst is removed from the reactor and immersed in a plating solution of a noble metal for undergoing a noble metal chemical substitution, thereby obtaining composite metal catalytic particles.

In this preferred embodiment, a thermal CVD process is used to form carbon nanotubes, which comprises the following steps:

The substrate deposited with composite metal catalytic particles according to the non-isothermal electroless deposition method is loaded in a high temperature furnace tube device. Acetylene is used as a carbon source gas, and argon gas is used as a protective gas for the cooling operation prior to and after the reaction. After the high temperature furnace heater is activated and the temperature reaches a reaction temperature, an ammonia gas is introduced for 10 minutes, and then an acetylene gas is introduced for 15 minutes. Upon completion of the growth of carbon nanotubes, the introduction of ammonia gas and acetylene are terminated. Argon gas as a protective gas is introduced for 10 minutes in order to avoid the occurrence of any undesirable reactions at a high temperature. The substrate with grown carbon nanotubes is removed from the furnace tube after the temperature of the furnace tube has reduced to room temperature, and a SEM and TEM are used to investigate the status of the grown carbon nanotubes.

The following examples are performed according to the above-mentioned embodiment of the present invention, and the reaction conditions of the examples are separately shown in the following. Even though the substrates used in the examples are separately p-type wafer and ITO-coated glass, and acetylene is used as a carbon source, the substrate and the carbon source gas suitable for use in the present invention are not limited by the examples and are limited only by the claims of the invention.

### EXAMPLE 1

### Carbon Nanotubes Grown on Silicon Wafer Deposited with Au—Ni Metal Particles.

A silicon wafer was deposited with Ni metal particles by a non-isothermal electroless deposition method, and then was loaded into a plating solution of a noble metal for undergoing a noble metal chemical substitution reaction in order to obtain Au—Ni composite metal catalytic particles on the surface of the substrate. Finally, the substrate was loaded into a high temperature furnace tube device to grow carbon nanotubes by a thermal CVD process. The operation temperatures of the CVD process were separately set at 800° C. and 400° C. An acetylene gas was introduced at a suitable flowrate and the operation time was 10 minutes. After the reaction, a FESEM was used to observe the growth status of carbon nanotubes on the silicon wafer substrate. The observation results indicate that carbon nanotubes are developed at reaction temperatures of 800° C. and 400° C. The chemical composition of the deposition solution in preparation of Ni metal particles according to this example are shown in the following:

| Composition of Ni electroless deposition | |
|---|---|
| solution | Concentration |
| Nickel sulfate (NiSO₄.6H₂O) | 0.11 M |
| Sodium hypophosphite (NaH₂PO₂.H₂O) | 0.28 M |
| Sodium lactate (C₃H₅O₃Na) | 0.36 M |
| Amino acetic acid (C₂H₅O₂N) | 0.13 M |
| Ammonium hydroxide (NH₄OH) | Adjusting the pH value of |
| | the deposition solution to 9 |

Furthermore, the composition of the plating solution used in the noble metal chemical substitution reaction in this example is shown in the following table, wherein the noble metal used in this example is Au:

| Composition of Au plating solution for | |
|---|---|
| chemical substitution | Concentration |
| Potassium gold cyanide [KAu(CN)₂] | 0.02 M |
| Ammonium chloride (NH₄Cl) | 1.1 M |
| Sodium citrate (Na₃C₆H₅O₇) | 0.2 M |
| Citric acid | Adjusting the pH value of |
| | the plating solution to 6 |

### EXAMPLE 2

### Carbon Nanotubes Grown on Silicon Wafer Deposited with Pd—Co Metal Particles.

A silicon wafer was deposited with Co metal particles by the non-isothermal electroless deposition method, and then was loaded into a plating solution of a noble metal for undergoing a noble metal chemical substitution reaction in order to obtain Pd—Co composite metal catalytic particles on the surface of the substrate. Finally, the substrate was loaded into a high temperature furnace tube device to grow carbon nanotubes by a thermal CVD process. The operation temperatures of the CVD process were set at 800° C. and 400° C. separately. An acetylene gas was introduced at a suitable flowrate and the operation time was 10 minutes. After the reaction, a FESEM was used to observe the growth status of carbon nanotubes on the silicon wafer substrate. The observation results indicate that carbon nanotubes are developed at reaction temperatures of 800° C. and 400° C. The chemical composition of the deposition solution in preparation of Co metal particles according to this example is shown in the following:

| Composition of Co electroless deposition | |
|---|---|
| solution | Concentration |
| Cobalt sulfate (CoSO₄.7H₂O) | 0.07 M |
| Sodium hypophosphite (NaH₂PO₂.H₂O) | 0.2 M |
| Sodium citrate (Na₃C₆H₅O₇) | 0.2 M |
| Ammonium chloride (NH₄Cl) | 0.55 M |
| Ammonium hydroxide (NH₄OH) | Adjusting the pH value of |
| | the deposition solution to 9 |

Furthermore, the composition of the plating solution used in the noble metal chemical substitution reaction in this example is shown in the following table, wherein the noble metal used in this example is Pd:

| Composition of Pd plating solution for | |
|---|---|
| chemical substitution | Concentration |
| Palladium chloride (PdCl₂) | 0.001 M |
| Hydrogen chloride (HCl) | Adjusting the pH value of |
| | the plating solution to 1 |

### EXAMPLE 3

### Carbon Nanotubes Grown on Silicon Wafer Deposited with Pd—Ni Metal Particles.

A silicon wafer was deposited with Ni metal particles by a non-isothermal electroless deposition method, and then was loaded into a plating solution containing a noble metal for undergoing a noble metal chemical substitution reaction in order to obtain Pd—Ni composite metal catalytic particles on the surface of the substrate. Finally, the substrate was loaded into a high temperature furnace tube device to grow carbon nanotubes by a thermal CVD process. The operation temperatures of the CVD process were separately set at 800° C. and 400° C. An acetylene gas was introduced at a suitable flowrate and the operation time was 10 minutes.

After the reaction, a FESEM was used to observe the growth status of carbon nanotubes on the silicon wafer substrate. The observation results indicate that carbon nanotubes are developed at reaction temperatures of 800° C. and 400° C. The chemical composition of the deposition solution in preparation of Ni metal particles according to this example was the same as the chemical composition of the deposition solution in preparation of Ni metal particles in Example 1; and the chemical composition of the plating solution used in the noble metal chemical substitution reaction according to this example was the same as the chemical composition of the Pd plating solution used in Example 2.

### EXAMPLE 4

### Carbon Nanotubes Grown on ITO-coated Glass Substrate Deposited with Pd—Ni Metal Particles.

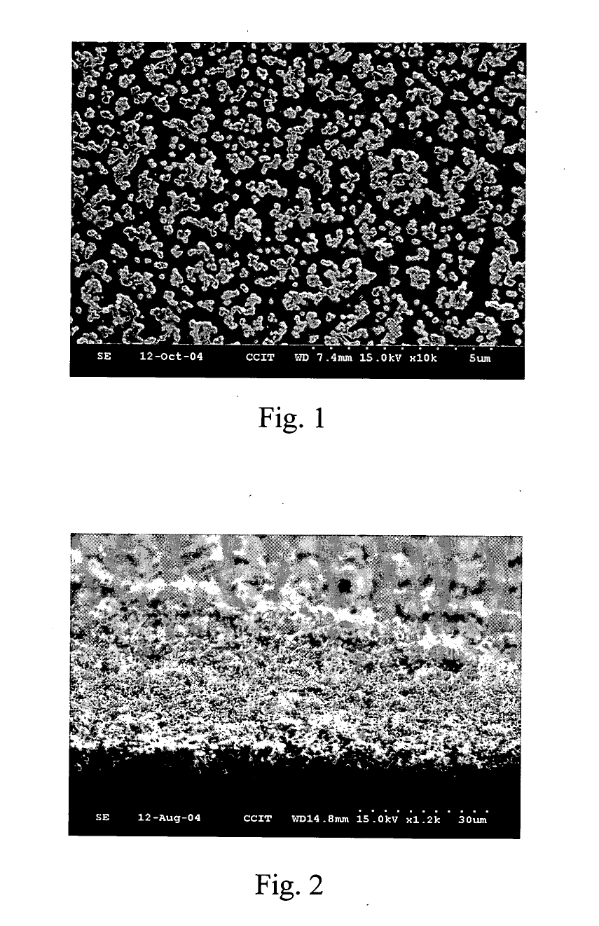

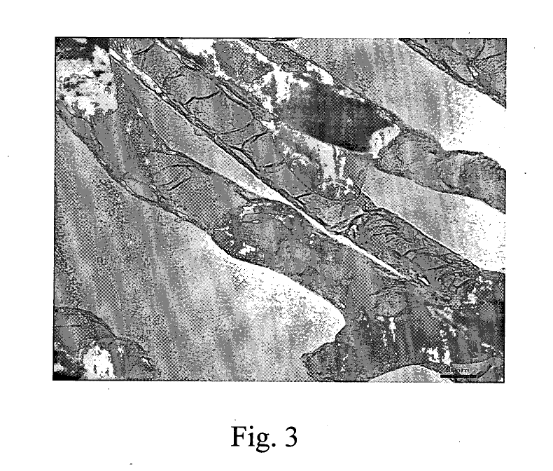

An ITO-coated glass substrate was deposited with Ni metal particles by a non-isothermal electroless deposition method, and a scanning electron microscope (SEM) was used to observe the deposited particles, as shown in FIG. 1. The method of the present invention is able to uniformly deposite Ni catalytic metal particles on the ITO-coated glass substrate. Next, the above substrate was immersed in a plating solution of a noble metal for undergoing a noble metal chemical substitution reaction in order to obtain Pd—Ni composite metal catalytic particles on the surface of the substrate. Finally, the substrate was loaded into a high temperature furnace tube device to grow carbon nanotubes by a thermal CVD process. The operation temperatures of the CVD process were separately set at 800° C. and 400° C. An acetylene gas was introduced at a suitable flowrate and the operation time was 10 minutes. After the reaction, a FESEM was used to observe the growth status of carbon nanotubes on the ITO-coated glass substrate. The observation results indicate that no carbon nanotubes are observed at the operation temperature of 800° C., because the glass was damaged at 800° C.; and carbon nanotubes are developed at the operation temperature of 400° C. FIG. 2 shows a SEM photo of carbon nanotubes prepared on the ITO-coated glass substrate by using the Pd—Ni composite metal catalyst at the operation temperature of 400° C. in this example. FIG. 3 shows a TEM photo of the carbon nanotubes shown in FIG. 2 with a greater magnification time. From this photo, the carbon nanotubes formed in this example are clearly shown.

The composition of the deposition solution used for the preparation of Ni metal particles in this example was the same as the composition of the deposition solution used in Example 1, and the composition of the plating solution used in the noble metal chemical substitution reaction in this example was the same as the composition of the Pd deposition solution used in Example 2.

The following control examples are for comparison with the above examples of the present invention, wherein some process conditions are altered, for example, catalytic metal, and process for forming catalytic metal, etc.

### Control 1

### Carbon Nanotubes Grown on Silicon Wafer without Using Catalytic Metal.

A clean silicon wafer was mounted in a high temperature furnace tube to grow carbon nanotubes thereon by a thermal CVD process. The operation temperatures were separately set at 800° C. and 400° C. Acetylene gas was introduced at a suitable flowrate. The operation time was 10 minutes. After the reaction, a FESEM was used to observe whether carbon nanotubes were grown on the silicon wafer substrate, and the observation indicates that no carbon nanotubes are grown on the silicon wafer substrate.

### Control 2

### Carbon Nanotubes Grown on Silicon Wafer Deposited with Ni Metal Film.

A silicon wafer was deposited with a Ni metal film catalyst by a sputtering process, and then was mounted into a high temperature furnace tube device to grow carbon nanotubes thereon by a thermal CVD process. The operation temperatures were separately set at 800° C. and 400° C. Acetylene gas was introduced at a suitable flowrate. The operation time was 10 minutes. After the reaction, a FESEM was used to observe whether carbon naotubes were grown on the silicon wafer substrate, and the observation indicates that carbon naotubes are grown on the silicon wafer substrate at the operation temperature of 800° C. and no carbon nanotubes are grown on the silicon wafer substrate at the operation temperature of 400° C.

### Control 3

### Carbon Nanotubes Grown on Silicon Wafer Deposited with Co Metal Film.

A silicon wafer was deposited with a Co metal film catalyst by a sputtering process, and then was mounted into a high temperature furnace tube device to grow carbon nanotubes thereon by a thermal CVD process. The operation temperatures were separately set at 800° C. and 400° C. Acetylene gas was introduced at a suitable flowrate. The operation time was 10 minutes. After the reaction, a FESEM was used to observe whether carbon nanotubes were grown on the silicon wafer substrate, and the observation indicates carbon nanotubes are grown on the silicon wafer substrate at the operation temperature of 800° C. and no carbon nanotubes are grown on the wafer substrate at the operation temperature of 400° C.

### Control 4

### Carbon Nanotubes Grown on ITO-coated Glass Substrate Deposited with Ni Metal Film.

An ITO-coated glass substrate was deposited with a Ni metal film catalyst by a sputtering process, and then was mounted into a high temperature furnace tube device to grow carbon nanotubes thereon by a thermal CVD process. The operation temperatures were separately set at 800° C. and 400° C. Acetylene gas was introduced at a suitable flowrate. The operation time was 10 minutes. After the reaction, a FESEM was used to observe whether carbon naotubes were grown on the silicon wafer substrate, and the observation indicates that the substrate is damaged at the operation temperature of 800° C. and no carbon nanotubes are grown on the glass substrate at the operation temperature of 400° C.

Table 1 lists the results for the above examples and controls. The results in Table 1 indicate that no carbon nanotubes are grown by a thermal CVD process at a lower temperature of 400° C. using the conventional single metal catalyst. However, the use of composite metal catalytic particles of the present invention is indeed able to grow carbon nanotubes at a lower temperature of 400° C. by using a thermal CVD process, and is applicable on various types of substrates.

TABLE 1

| | Process | Type of | Type of | Formation of carbon |
|---|---|---|---|---|
| | temperature | substrate | catalyst | nanotubes |
| Example 1 | 800° C. and | Si wafer | Au—Ni | Yes at both |
| | 400° C. | | composite | temperatures |
| | | | metal | |
| Example 2 | 800° C. and | Si wafer | Pd—Ni | Yes at both |
| | 400° C. | | composite | temperatures |
| | | | metal | |
| Example 3 | 800° C. and | Si wafer | Pd—Ni | Yes at both |
| | 400° C. | | composite | temperatures |
| | | | metal | |
| Example 4 | 800° C. and | ITO-coated | Pd—Ni | Substrate damaged |
| | 400° C. | glass | composite | at 800° C.; growth |
| | | | metal | at 400° C. |
| Control 1 | 800° C. and | Si wafer | no | No at both |
| | 400° C. | | | temperatures |
| Control 2 | 800° C. and | Si wafer | Ni | 800° C. - Yes; |
| | 400° C. | | | 400° C. - No |
| Control 3 | 800° C. and | Si wafer | Co | 800° C. - Yes; |
| | 400° C. | | | 400° C. - No |
| Control 4 | 800° C. and | ITO-coated | Ni | Substrate damaged |
| | 400° C. | glass | | at 800° C.; |
| | | | | 400° C. - No |

The above-mentioned examples are for illustrative only and not for limiting the scope of the present invention which is defined by the claims appended.

1. A method for preparing carbon nanotubes at a low temperature, which comprises the following steps:
(a) providing a first metal chemical deposition solution, a substrate, and a reactor, wherein said first metal chemical deposition solution is loaded in said reactor, and said substrate is immersed in said chemical deposition solution, and said reactor is provided with a heater and a cooler;
(b) heating said chemical deposition solution by using said heater, and cooling the heated chemical deposition solution by using said cooler;
(c) performing an electroless plating reaction to form at least a first metal particle on a surface of said substrate, wherein said surface of said substrate is placed near to said heater with a gap being formed therebetween;
(d) substituting a portion of the first metal particles on the surface of said substrate with a second metal by using a chemical metal substitution process to form composite metal particles on the surface of said substrate; and
(e) forming carbon nanotubes on the surface of said substrate;
wherein, said first metal chemical deposition solution comprises a metal salt as a source of the first metal, a reduction agent, a complexing agent, and a pH adjustment agent.

2. The method as claimed in claim 1, wherein said first metal is selected from the group consisting of Fe, Co, Ni, and an alloy thereof.

3. The method as claimed in claim 1, wherein said second metal is selected from the group consisting of Au, Pd, Pt, and Ag.

4. The method as claimed in claim 1, wherein said metal salt is selected from the group consisting of nickel sulfate, nickel chloride, cobalt sulfate, cobalt chloride, ferric sulfate, and a combination thereof.

5. The method as claimed in claim 1, wherein said reduction agent is selected from the group consisting of sodium hypophosphite, hydrazine sulfate, and a combination thereof.

6. The method as claimed in claim 1, wherein said complexing agent is selected from the group consisting of amino acetic acid, sodium lactate, and a combination thereof.

7. The method as claimed in claim 1, wherein said substrate is selected from the group consisting of single-crystal silicon wafer, glass with a coating of poly-silicon, glass with a coating of amorphous silicon and glass with a coating of indium-tin-oxide (ITO).

8. The method as claimed in claim 1, wherein step (e) comprising carrying out a thermal chemical vapor deposition (CVD) process to form carbon nanotubes.

9. The method as claimed in claim 8, wherein said CVD process comprises the following steps: (I) providing a gas as a carbon source, an argon gas as a protective gas for protecting said substrate before and after the CVD reaction, and a high temperature furnace device; (II) installing said substrate from step (d) in said high temperature furnace device, while concurrently introducing said argon gas; (III) heating said high temperature furnace to a reaction temperature, and sequentially and separately introducing an ammonia gas and said carbon source gas into said high temperature furnace to form carbon nanotubes; and (IV) upon completion of the growth of carbon nanotubes, introducing the argon gas and removing said substrate from the furnace.

10. The method as claimed in claim 9, wherein said reaction temperature is 400° C. or higher.

11. The method as claimed in claim 9, wherein said carbon source gas is selected from the group consisting of CO, methanol, toluene, acetylene, methane, and a combination thereof.

12. The method of claim 1, wherein the gap is of 10 μm-1000 μm.
